(19) United States
(12) Patent Application Publication
(10) Pub. No.: US 2018/0097182 A1
(43) Pub. Date: Apr. 5, 2018

(54) ORGANIC OPTOELECTRONIC DEVICE

(71) Applicant: Sumitomo Chemical Company Limited, Tokyo (JP)

(72) Inventor: Philip Benzie, Godmanchester (GB)

(73) Assignee: Sumitomo Chemical Company Limited, Tokyo (JP)

(21) Appl. No.: 15/714,317

(22) Filed: Sep. 25, 2017

(30) Foreign Application Priority Data
Sep. 30, 2016 (GB) 1616717.3

(51) Int. Cl. H01L 51/00

(52) U.S. Cl. CPC H01L 51/0039; H01L 51/5221; H01L 51/0081

(57) ABSTRACT

An organic optoelectronic device, such as an organic light-emitting device, comprising an anode (2), a cathode (6) and at least one organic semiconducting layer, optionally an organic light-emitting layer (4), between the anode and the cathode, wherein the cathode comprises a first conducting layer (63) comprising a first pattern (63A) comprising a first metal and a second pattern (63B) comprising a second metal that is different from the first metal. A layer of a metal compound (61) may be provided between the one or more organic semiconducting layers and the first conductive layer.

### RELATED INVENTIONS

This application claims the benefits under 35 U.S.C. § 119(a)-(d) or 35 U.S.C. § 365(b) of British application number GB1616717.3, filed Sep. 30, 2017, the entirety of which is incorporated herein by reference.

### FIELD OF THE INVENTION

This invention relates to organic optoelectronic devices, in particular organic light emitting devices, and methods of making the same.

### BACKGROUND OF THE INVENTION

Electronic devices comprising active organic materials are attracting increasing attention for use in devices such as organic light emitting diodes, organic photovoltaic devices, organic photosensors, organic transistors and memory array devices. Devices comprising organic materials offer benefits such as low weight, low power consumption and flexibility.

Moreover, use of soluble organic materials allows use of solution processing in device manufacture, for example inkjet printing or spin-coating.

An organic light-emissive device (“OLED”) comprises an anode, a cathode and a light-emitting layer between the anode and cathode containing one or more light-emitting layers. Organic light-emitting materials include polymeric light-emitting materials, for example as disclosed in WO90/13148, and non-polymeric materials, such as (8-hydroxyquinoline) aluminium (“Alq3”) disclosed in U.S. Pat. No. 4,539,507.

In operation of an OLED, holes are injected into the device through the anode and electrons are injected into the device through the cathode. The holes and electrons combine in the organic electroluminescent layer to form an exciton which then undergoes radiative decay to give light.

Photoresponsive devices comprise a p-type organic semiconductor and a n-type semiconductor forming a heterojunction between an anode and cathode. In operation, light incident on the device undergoes photoinduced charge separation.

OLEDs may be fabricated on a glass or plastic substrate coated with a transparent anode such as indium-tin-oxide (“ITO”) and in use light may be emitted through the transparent anode and transparent substrate.

Appl. Phys. Lett. 70, 152, 1997 discloses a cathode comprising a bilayer of lithium fluoride and aluminium adjacent to an electron-transporting layer. The device is reported to have higher efficiency compared to a device with a Mg/Ag alloy cathode. The improvement is attributed to band bending of the organic electron-transporting layer in contact with the lithium fluoride.

U.S. Pat. No. 5,739,635 discloses organic electroluminescent devices comprising a cathode made of a conductive material and an electron injecting layer selected from the group consisting of alkaline metal oxides, alkaline metal peroxides, alkaline metal compound oxides, alkaline metal halides, alkaline metal nitrides and alkaline metal salts.

### SUMMARY OF THE INVENTION

In a first aspect the invention provides an organic optoelectronic device comprising an anode, a cathode and at least one organic semiconducting layer between the anode and the cathode, wherein the cathode comprises a first conducting layer comprising a first pattern comprising a first metal and a second pattern comprising a second metal that is different from the first metal.

In a second aspect the invention provides a method of forming an organic optoelectronic device according to the first aspect, the method comprising the step of forming the first pattern on an underlying layer of the device and forming the second pattern on regions of the underlying layer not covered by the first pattern

### DESCRIPTION OF THE DRAWINGS

FIG. 1A is a schematic illustration of a cross-section of a device according to an embodiment of the invention;

FIG. 1B is a plan view of the device of FIG. 1A;

FIG. 2 illustrates a method of forming a device according to an embodiment of the invention; and

FIG. 3 is a schematic illustration of a cross-section of a device according to a further embodiment of the invention.

### DETAILED DESCRIPTION OF THE INVENTION

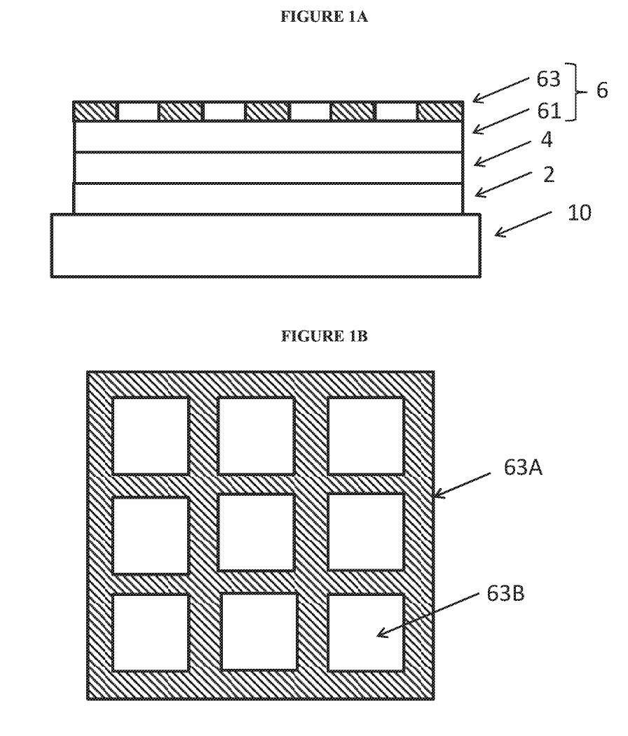

With reference to FIG. 1A, which is not drawn to any scale, an organic light-emitting device according to an embodiment of the invention comprises a transparent anode 2, a cathode 6 and a light-emitting layer 4 between the anode and the cathode. The device is supported on a transparent substrate 10, for example glass or transparent plastic. In operation, light emitted from light-emitting layer 4 escapes through the transparent anode 2. The cathode 6 preferably comprises a reflective surface for reflection towards the anode of light emitted from the light-emitting layer 4 or light reflected within the device.

Further layers (not shown) may be provided between the anode and the cathode including, without limitation, one or more further light-emitting layers, one or more hole-transporting layers, one or more electron-transporting layers, one or more hole-blocking layers, one or more electron-blocking layers, one or more hole-injection layers and one or more electron-injection layers.

Exemplary OLED structures including one or more further layers include the following:

Anode/Hole-injection layer/Light-emitting layer/Cathode

Anode/Hole transporting layer/Light-emitting layer/Cathode

Anode/Hole-injection layer/Hole-transporting layer/Light-emitting layer/Cathode

Anode/Hole-injection layer/Hole-transporting layer/Light-emitting layer/Electron-transporting layer/Cathode.

The anode may comprise or consist of a transparent conducting materials, for example indium tin oxide or indium zinc oxide or a transparent organic conducting material for example PEDOT/PSS.

The cathode 6 comprises a first conductive layer 63 and a metal compound layer 61 between the first conductive layer 63 and the light-emitting layer 4. A first surface of the metal compound layer 61 may be in contact with an organic layer which may be the organic light-emitting layer 4 as shown in FIG. 1A or, if present, another organic layer, for example an electron-transporting layer or electron-injecting layer between the light-emitting layer 4 and the metal compound layer 61. A second surface of the metal compound layer 61 is preferably in contact with the first conductive layer 63.

Preferably, the metal compound is an alkali or alkali earth compound. Preferably, the metal compound is a halide, more preferably a fluoride.

Exemplary metal compounds include, without limitation, lithium fluoride, sodium fluoride, potassium fluoride, rubidium fluoride, cesium fluoride, beryllium fluoride, magnesium fluoride, calcium fluoride, strontium fluoride and barium fluoride. Alkali metal fluorides are particularly preferred.

With reference to FIG. 1B, the first conductive layer 63 comprises a first pattern 63A comprising or consisting of a first metal, and a second pattern 63B comprising or consisting of a second metal. The first and second metals are different. If the first or second pattern comprises one or more materials in addition to the first or second metal respectively then the first pattern preferably does not comprise the second metal and the second pattern preferably does not comprise the first metal.

The first pattern 63A of FIG. 1B is in the pattern of a grid and the second pattern 63B is in the pattern defined by grid spaces. It will be appreciated that the first and second patterns may form different patterns including, without limitation, alternating lines of the first and second patterns or a tiled pattern, for example a checkerboard pattern.

The first pattern may form a continuous pattern, such as the grid 63A of FIG. 1B, or may form a non-continuous pattern, such as a plurality of islands comprising the first metal. Preferably, the first pattern is a continuous or non-continuous pattern extending across all or substantially all (e.g. 80-90%) of the width and length of the metal compound layer, but only partially covering the metal compound layer.

The second pattern may form a non-continuous pattern, such as the plurality of islands 63B comprising the second metal in the grid spaces of FIG. 1B, separated from one another by the first pattern, or may form a continuous pattern such as a grid.

The first and second patterns together form a first conductive layer 63 of the cathode. The patterns of the first and second patterns are preferably complementary, with no gaps between the first and second patterns at the interface with the layer that the first conductive layer 63 is in contact with. In other embodiments conductive layer 63 may comprise one or more further patterns, each comprising a material or material composition different from the material or material composition of the first and second patterns.

The area of the first pattern at a surface of cathode layer 63 with metal compound layer 61 is preferably less than 50% of the total surface area of cathode layer 63.

The first pattern preferably comprises or consists of at least one metal having a work function of less than 4.0 eV, preferably less than 3.8 eV.

More preferably, the first pattern comprises or consists of magnesium.

The second pattern preferably has high reflectivity. More preferably, the second pattern comprises or consists of magnesium. The second metal may have a work function of at least 4.0 eV, optionally at least 4.2 eV.

Work functions of elemental metals are as given in the CRC Handbook of Chemistry and Physics, 87^{th} Edition, 12-114. For any given element, the first work function value applies if more than one work function value is listed.

The first pattern preferably has a thickness in the range of 0.5-20 nm, preferably in the range of 0.5-5 nm or 1-5 nm.

To form the cathode layer 63, one of the first and second patterns may be formed on the metal compound layer 61 followed by formation of the other of the first and second patterns.

It will be appreciated that the thickness of the pattern that is deposited first determines the maximum thickness of the first conductive layer 63.

Preferably the first metal, and any other components of the first pattern, are deposited first to form the first conductive pattern 63A. The second metal, and any other components of the second pattern, may be deposited to the same thickness or to a different thickness as the first pattern.

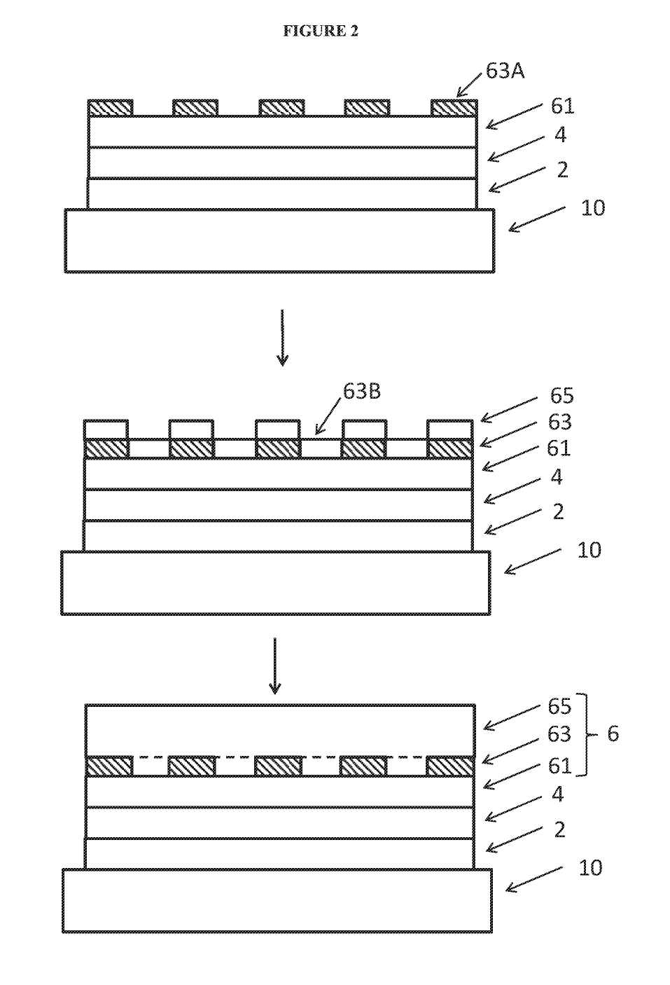

FIG. 2 illustrates a process according to an embodiment of the invention for forming a device.

The first pattern 63A is formed by any suitable technique known to the skilled person, for example thermal or e-beam evaporation through a shadow mask, onto an underlying layer.

The second pattern 63B may also be formed using a patterning technique, however it is preferred that the second pattern is formed by depositing the second metal, and any other components of the second pattern, by a non-selective method such as thermal or e-beam evaporation without a shadow mask. By use of a non-selective deposition method, the second metal is deposited on the surface of the underlying layer not covered by the first pattern and on the first pattern, thereby forming a second conductive layer 65 on the first conductive layer 63.

The second metal may be deposited to substantially the same thickness as the first metal, or the second metal may be deposited to a thickness greater than the thickness of the first pattern, resulting in formation of a second cathode layer 65 extending across the first and second patterns of conductive layer 63.

It will therefore be appreciated that the second pattern 63B of the first conductive layer 63 and the second conductive layer 65 may consist of the same material or materials and may be formed in a single deposition step.

The second cathode layer preferably has a thickness of at least 20 nm, optionally at least 50 nm. The second cathode layer optionally has a thickness of up to about 500 nm or about 200 nm.

The cathode may or may not comprise one or more further conductive layers (not shown).

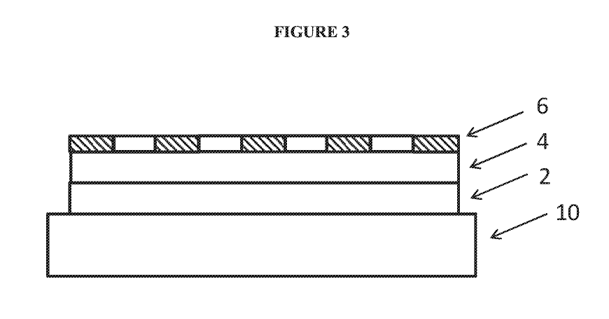

FIG. 3 illustrates an OLED according to a further embodiment of the invention. The OLED of FIG. 3 is as described with respect to FIGS. 1 and 2 except that the first conductive layer 63 is in direct contact with organic light-emitting layer 4. The cathode may consist of the first conductive layer 63 or may comprise one or more further conductive layers. In other embodiments, the first conductive layer may be in direct contact with an organic layer of the device other than the light-emitting layer, for example an organic electron-transporting layer or an organic electron-injection layer between the light-emitting layer and the first conductive layer.

Light-Emitting Layer

The OLED may contain one or more light-emitting layers, the or each light-emitting layer comprising or consisting of at least one organic light-emitting material.

Light-emitting materials may be fluorescent materials, phosphorescent materials or a mixture of fluorescent and phosphorescent materials. Light-emitting materials may be selected from polymeric and non-polymeric light-emitting materials. Exemplary light-emitting polymers are conjugated polymers, for example polyphenylenes and polyfluorenes examples of which are described in Bernius, M. T., Inbasekaran, M., O'Brien, J. and Wu, W., Progress with Light-Emitting Polymers. Adv. Mater., 12 1737-1750, 2000, the contents of which are incorporated herein by reference. A light-emitting layer may comprise a host material and a fluorescent or phosphorescent light-emitting dopant. Exemplary phosphorescent dopants are row 2 or row 3 transition metal complexes, for example complexes of ruthenium, rhodium, palladium, rhenium, osmium, iridium, platinum or gold.

A light-emitting layer of an OLED may be unpatterned, or may be patterned to form discrete pixels. Each pixel may be further divided into subpixels. The light-emitting layer may contain a single light-emitting material, for example for a monochrome display or other monochrome device, or may contain materials emitting different colours, in particular red, green and blue light-emitting materials for a full-colour display.

A light-emitting layer may contain a mixture of more than one light-emitting material, for example a mixture of light-emitting materials that together provide white light emission. A plurality of light-emitting layers may together produce white light. White-emitting OLEDs as described herein may have a CIE x coordinate equivalent to that emitted by a black body at a temperature in the range of 2500-9000K and a CIE y coordinate within 0.05 or 0.025 of the CIE y co-ordinate of said light emitted by a black body, optionally a CIE x coordinate equivalent to that emitted by a black body at a temperature in the range of 2700-6000K.

Charge Transporting, Charge Injecting and Charge Blocking Layers

A hole transporting layer may be provided between the anode and the light-emitting layer or layers. An electron transporting layer may be provided between the cathode and the light-emitting layer or layers.

An electron blocking layer may be provided between the anode and the light-emitting layer and a hole blocking layer may be provided between the cathode and the light-emitting layer. Transporting and blocking layers may be used in combination. Depending on its HOMO and LUMO levels, a single layer may both transport one of holes and electrons and block the other of holes and electrons.

A hole transporting layer preferably has a HOMO level of less than or equal to 5.5 eV, more preferably around 4.8-5.5 eV as measured by square wave voltammetry. The HOMO level of the hole transport layer may be selected so as to be within 0.2 eV, optionally within 0.1 eV, of an adjacent layer (such as a light-emitting layer) in order to provide a small barrier to hole transport between these layers. The hole-transporting layer may be a polymer comprising arylamine repeat units, for example as described in WO 99/54385, WO 2005/049546, WO2013/108022 or WO2013/108023, the contents of which are incorporated herein by reference.

An electron transporting layer located between the light-emitting layers and cathode preferably comprises or consists of a material having a LUMO level of around 2.5-3.5 eV as measured by square wave voltammetry. A n-doped electron-transporting material may be provided between the light-emitting layer and the cathode.

A conductive hole injection layer, which may be formed from a conductive organic or inorganic material, may be provided between the anode and the light-emitting layer of an OLED. Examples of doped organic hole injection materials include optionally substituted, doped poly(ethylene dioxythiophene) (PEDT), in particular PEDT doped with a charge-balancing polyacid such as polystyrene sulfonate (PSS) as disclosed in EP 0901176 and EP 0947123, polyacrylic acid or a fluorinated sulfonic acid, for example Nafion®; polyaniline as disclosed in U.S. Pat. No. 5,723,873 and U.S. Pat. No. 5,798,170; and optionally substituted polythiophene or poly(thienothiophene). Examples of conductive inorganic materials include transition metal oxides such as VOx MoOx and RuOx as disclosed in Journal of Physics D: Applied Physics (1996), 29(11), 2750-2753.

### EXAMPLES

### Device Example 1

An organic light-emitting device having the following structure was prepared:

ITO/HTL/HIL/LEL/ETL/NaF/Mg—Ag/Ag

wherein ITO is an indium-tin oxide anode; HIL is a hole-injecting layer comprising a hole-injecting material, HTL is a hole-transporting layer comprising a hole-transporting material; LEL is a light-emitting layer; ETL is an electron-transporting layer comprising an electron-transporting compound; NaF is a layer of sodium fluoride; Mg—Ag is a patterned layer of a magnesium pattern and a silver pattern; and Ag is a layer of silver over the patterned layer.

A substrate carrying ITO was cleaned using UV/Ozone. A hole injection layer was formed by spin-coating a formulation of a hole-injection material available from Nissan Chemical Industries. A hole-transporting layer comprising a crosslinkable hole-transporting material was formed by spin coating following by heating to crosslink the hole-transporting material. The light-emitting layer was formed a thickness of about 70-80 nm by spin-coating a light-emitting material. The electron-transporting layer was formed by spin-coating an electron transporting material. To form the cathode, sodium fluoride, magnesium and silver were each deposited through a shadow mask to thicknesses of about 3.5 nm, 2 nm and 100 nm respectively to form a grid on the surface of the electron-transporting layer, and sodium fluoride and silver were again deposited without a shadow mask.

Although the invention has been described herein with reference to organic light-emitting diodes, it will be understood that the invention is applicable to organic photoresponsive devices such as organic photovoltaic devices or organic photodetector devices having structures as described herein except that the at least one light-emitting layer is replaced with a layer of a p-type organic semiconductor and a layer of an n-type organic semiconductor or a single layer comprising a mixture of a p-type organic semiconductor and an n-type organic semiconductor

Although the present invention has been described in terms of specific exemplary embodiments, it will be appreciated that various modifications, alterations and/or combinations of features disclosed herein will be apparent to those skilled in the art without departing from the scope of the invention as set forth in the following claims.

1. An organic optoelectronic device comprising an anode, a cathode and at least one organic semiconducting layer between the anode and the cathode, wherein the cathode comprises a first conducting layer comprising a first pattern comprising a first metal and a second pattern comprising a second metal that is different from the first metal.

2. An organic optoelectronic device according to claim 1 wherein the first pattern consists of the first metal.

3. An organic optoelectronic device according to claim 1 wherein the first metal has a work function of less than 4.0 eV.

4. An organic optoelectronic device according to claim 3 wherein the first metal is magnesium.

5. An organic optoelectronic device according to claim 1 wherein the second pattern consists of the second metal.

6. An organic optoelectronic device according to claim 1 wherein the second metal has a work function greater than 4.0 eV.

7. An organic optoelectronic device according to claim 6 wherein the second metal is silver.

8. An organic optoelectronic device according to claim 1 wherein the first conducting layer has a thickness of 0.5-20 nanometres.

9. An organic optoelectronic device according to claim 1 wherein a layer comprising a metal compound is provided between the one or more organic semiconducting layers and the first conducting layer.

10. An organic optoelectronic device according to claim 9 wherein the metal compound is an alkali or alkali metal earth compound.

11. An organic optoelectronic device according to claim 9 wherein the metal compound is a fluoride.

12. An organic optoelectronic device according to claim 1 wherein the area of the first pattern at a surface of the cathode layer in contact with another layer of the device is less than 50% of a total surface area of cathode layer.

13. An organic optoelectronic device according to claim 12 wherein the surface of the cathode layer is in contact with a layer comprising a metal compound between the one or more organic semiconducting layers and the first conducting layer.

14. An organic optoelectronic device according to claim 1 wherein the device further comprises a second conducting layer.

15. An organic optoelectronic device according to claim 14 wherein the second conducting layer comprises or consists of the second metal.

16. An organic optoelectronic device according to claim 1 wherein the organic optoelectronic device is an organic light-emitting device and the at lease one organic semiconducting layer comprises at least one organic light-emitting layer.

17. A method of forming an organic optoelectronic device according to claim 1, the method comprising the step of forming the first pattern on an underlying layer of the device and forming the second pattern on regions of the underlying layer not covered by the first pattern.

18. A method according to claim 17 wherein the first pattern is formed by depositing the first metal and any further components of the first pattern onto the underlying layer through a shadow mask.

19. A method according to claim 17 wherein the second pattern is formed by depositing the second metal and any further components of the second pattern onto the underlying layer and the first pattern.

20. A method according to claim 17 wherein the underlying layer is a layer comprising a metal compound.
